(19) United States
(12) Patent Application Publication
(10) Pub. No.: US 2026/0075872 A1
(43) Pub. Date: Mar. 12, 2026

(54) SEMICONDUCTOR DEVICE

(71) Applicant: FUJI ELECTRIC CO., LTD., Kawasaki-shi (JP)

(72) Inventor: Akimasa KINOSHITA, Matsumoto-city (JP)

(73) Assignee: FUJI ELECTRIC CO., LTD., Kawasaki-shi (JP)

(21) Appl. No.: 19/284,051

(22) Filed: Jul. 29, 2025

(30) Foreign Application Priority Data
Sep. 6, 2024 (JP) 2024-154017

(51) Int. Cl. H10D 30/66

(52) U.S. Cl. CPC H10D 30/665; H10D 30/668

(57) ABSTRACT

A semiconductor device, including: a semiconductor substrate having a first main surface and a second main surface opposite to each other, the semiconductor substrate having a termination region surrounding a periphery of an active region in a plan view thereof; an insulating layer covering the first main surface of the semiconductor substrate in the termination region; and a surface protective film provided on the insulating layer in the termination region. The first main surface has: a first portion at an outer periphery of the semiconductor substrate, and a second portion closer to the active region than is the first portion, the first portion being recessed to be closer to the second main surface of the semiconductor substrate than is the second portion, thereby forming a step with the second portion. The surface protective film covers the step, via the insulating layer.

### CROSS REFERENCE TO RELATED APPLICATIONS

This application is based upon and claims the benefit of priority of the prior Japanese Patent Application No. 2024-154017, filed on Sep. 6, 2024, the entire contents of which are incorporated herein by reference.

### BACKGROUND OF THE INVENTION

### 1. Field of the Invention

Embodiments of the disclosure relate to a semiconductor device.

### 2. Description of the Related Art

Japanese Patent No. 7085959 describes a device in which a protective metal film is provided on an outer edge portion of an oxide protective film at a surface of an epitaxial layer, whereby moisture resistance against moisture penetrating in to a polyimide protective film is improved. Japanese Laid-Open Patent Publication No. 2023-172987 describes a device in which, on an upper surface of a semiconductor substrate, in a termination region, multiple grooves extending along an outer peripheral end of organic insulating film are provided, whereby moisture resistance against moisture penetrating in from the outer peripheral end of the organic insulating film is improved.

### SUMMARY OF THE INVENTION

According to an embodiment of the present disclosure, a semiconductor device includes: a semiconductor substrate having a first main surface and a second main surface opposite to each other, the semiconductor substrate further having: an active region through which a main current flows, and a termination region surrounding a periphery of the active region in a plan view of the semiconductor device; an insulating layer covering the first main surface of the semiconductor substrate in the termination region; and a surface protective film provided on the insulating layer in the termination region. The first main surface has a first portion at an outer periphery of the semiconductor substrate, and a second portion closer to the active region than is the first portion, the first portion being recessed to be closer to the second main surface of the semiconductor substrate than is the second portion, thereby forming a step with the second portion, and the surface protective film covers the step, via the insulating layer.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a semiconductor device according to an embodiment is viewed from a front surface of a semiconductor substrate thereof.

FIG. 2 is a cross-sectional view depicting a structure along cutting line A-A′ in FIG. 1.

FIG. 3 is an enlarged view a cross-sectional view of a vicinity of a chip end in FIG. 2.

FIG. 4 is a cross-sectional view depicting a state of the semiconductor device according to the first embodiment during manufacture.

FIG. 5 is a cross-sectional view depicting a state of the semiconductor device according to the first embodiment during manufacture.

FIG. 6 is a cross-sectional view depicting a state of the semiconductor device according to the first embodiment during manufacture.

FIG. 7 is a cross-sectional view depicting a state of the semiconductor device according to the first embodiment during manufacture.

FIG. 8 is a cross-sectional view depicting a structure of a semiconductor device according to the second embodiment.

FIG. 9 is a cross-sectional view depicting a structure of a semiconductor device according to the third embodiment.

### DETAILED DESCRIPTION OF THE INVENTION

First, problems associated with the conventional techniques are discussed. In both Japanese Patent No. 7085959 and Japanese Laid-Open Patent Publication No. 2023-172987, the length (length in a direction from a center of the semiconductor substrate to an outer peripheral end) of the termination region increases due to the protective metal film and the grooves being disposed and thus, the surface area (chip area) and cost of the semiconductor substrate increase.

An outline of an embodiment of the present disclosure is described. (1) A semiconductor device according to one aspect of the present disclosure is as follows. A semiconductor substrate has an active region through which a main current flows and a termination region surrounding a periphery of the active region in a plan view. The termination region includes: a scribe line left in an outer periphery of the semiconductor substrate, an insulating layer covering a first main surface of the semiconductor substrate, and a surface protective film provided on the insulating layer. The first main surface has a first portion and a second portion closer to the active region than is the first portion, the first portion being recessed closer to the second main surface of the semiconductor substrate than is the second portion, thereby forming a step. The surface protective film covers the step, via the insulating layer.

According to the disclosure above, moisture (water vapor) flowing in from the outer peripheral end of the surface protective film does not easily flow inward from the step (outer peripheral step) of the first main surface of the semiconductor substrate and thus, the moisture resistance of the semiconductor device may be improved. The step of the front surface of the semiconductor substrate is a simple structure and may be easily formed by etching or the like, thereby enabling increases in cost to be suppressed.

(2) Further, the semiconductor device according to one aspect of the present disclosure is as follows. A semiconductor substrate has an active region through which a main current flows and a termination region surrounding a periphery of the active region in a plan view. The termination region has a channel stopper region provided in an outer peripheral portion of the semiconductor substrate, an insulating layer covering the first main surface of the semiconductor substrate, and a surface protective film provided on the insulating layer. The channel stopper region is provided along the first main surface. The first main surface has a first portion on the channel stopper region, extending a predetermined width toward the active region from an outer periphery of the semiconductor substrate and a second portion closer to the active region than is the first portion, the first portion being recessed closer to the second main surface of the semiconductor substrate than is the second portion, thereby forming a step. The surface protective film covers the step, via the insulating layer.

According to the disclosure above, moisture (water vapor) that flows in from the outer peripheral end of the surface protective film does not easily flow toward the active region from the step (outer peripheral step) of the first main surface of the semiconductor substrate and thus, the moisture resistance of the semiconductor device may be improved. The step of the front surface of the semiconductor substrate is a simple structure and may be easily formed by etching or the like, thereby enabling increases in cost to be suppressed.

(3) Further, the semiconductor device according to the present disclosure, in (1) or (2) described above, the surface protective film may terminate above the first portion, via the insulating layer and a portion of the surface protective film above the first portion may have an inclined surface inclined a predetermined angle with respect to the first portion.

According to the disclosure above, before the semiconductor chips (semiconductor substrates) are cut (diced) from a semiconductor wafer, a portion of the surface protective film on the scribe line is removed, whereby the outer end surface portion of the surface protective film is an inclined surface. During dicing of the semiconductor wafer, above the scribe line is free of the surface protective film and thus, processing debris generated by the dicing blade, etc. may be suppressed.

(4) Further, the semiconductor device according to the present disclosure, in any one of (1) to (3) described above, the first main surface may have a third portion connecting the first portion and the second portion, the third portion may have the step forming a tapered shape and may have an incline angle of 45 degrees or more but not more than 90 degrees with respect to the second portion.

According to the disclosure above, an inflow of moisture from the outer peripheral step of the first main surface of the semiconductor substrate may be further suppressed.

(5) Further, the semiconductor device according to the present disclosure, in any one of (1) to (3) described above, the first main surface may have a third portion connecting the first portion and the second portion, the third portion may have the step forming a reverse tapered shape and may have an incline angle of 45 degrees or more but not more than 90 degrees with respect to the first portion.

According to the disclosure above, an inflow of moisture from the outer peripheral step of the first main surface of the semiconductor substrate may be further suppressed.

(6) Further, the semiconductor device according to the present disclosure, in any one of (1) to (4) described above, the first portion has a sub-trench, and the insulating layer is provided along an inner wall of the sub-trench.

According to the disclosure above, an inflow of moisture from the outer peripheral step of the first main surface of the semiconductor substrate may be further suppressed.

(7) Further, the semiconductor device according to the present disclosure, in (6) described above, the sub-trench may have a depth of 0.1 μm or more but not more than 1 μm.

According to the disclosure above, coverage of the insulating layer may be improved.

(8) Further, the semiconductor device according to the present disclosure, in (1) described above, a channel stopper region may be provided along the step, in the outer peripheral portion of the semiconductor substrate.

According to the disclosure above, concentration of electric field at the outer peripheral step of the first main surface of the semiconductor substrate when the semiconductor device is off may be suppressed.

(9) Further, the semiconductor device according to the present disclosure, in any one of (2) to (8) described above, the channel stopper region may be provided along the first portion, may extend toward active region from the first portion and along the step, and may reach the second portion.

According to the disclosure above, spreading of a depletion layer in a direction from a center to an end of the semiconductor substrate when the semiconductor device is off may be suppressed in a vicinity of the second portion of the first main surface of the semiconductor substrate.

(10) Further, the semiconductor device according to the present disclosure, in any of (1) to (9) described above, the surface protective film may contain a polyimide.

According to the disclosure above, stress occurring in the semiconductor substrate may be reduced by the surface protective film. Further, adverse effects on the semiconductor device due to environmental changes may be reduced. Thus, the reliability of the semiconductor device may be improved.

Findings underlying the present disclosure are discussed. In general, a semiconductor device has a surface protective film containing a polyimide, at an outermost surface of a front surface of a semiconductor substrate (semiconductor chip), in an edge termination region and is susceptible to an intrusion of moisture (water vapor) from the outer peripheral end (end of closest to a chip end) of the surface protective film, the moisture (water vapor) being in air that has become humid over time. Moisture that flows in from the peripheral end of the surface protective film flows along an interface between the surface protective film and an insulating film therebelow and toward an active region (toward a chip center) and thus, peeling of the surface protective film may occur and a voltage withstanding structure of the edge termination region may be adversely affected. Japanese Patent No. 7085959 and Japanese Laid-Open Patent Publication No. 2023-172987 disclose structures for improving moisture resistance against moisture that flows in from the outer peripheral end of the surface protective film.

However, in Japanese Patent No. 7085959 and Japanese Laid-Open Patent Publication No. 2023-172987, the structure (protective metal film with high moisture resistance, grooves having a trapezoidal shape in a cross-sectional view) for improving moisture resistance is disposed, whereby the chip surface area and product cost increase. Further, in Japanese Patent No. 7085959, a photomask for partially leaving the protective metal film and additional processes are necessary, making the processes complicated. In Japanese Laid-Open Patent Publication No. 2023-172987, a process for forming the grooves having a trapezoidal shape in a cross-sectional view is complicated. Thus, manufacturing costs increase. Further, in Japanese Patent No. 7085959, depending on the arrangement of the protective metal film, the protective metal film may be scraped off by a dicing blade or the like and scattered or the protective metal film may peel off.

In the present embodiment, a low-cost semiconductor device in which moisture resistance is improved by an easily formed structure is provided. Further, adhesion with the resin of a package in which the semiconductor device mounted is improved.

Embodiments of a semiconductor device according to the present invention are described in detail with reference to the accompanying drawings.

In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical will be given the same reference numerals and are not repeatedly described.

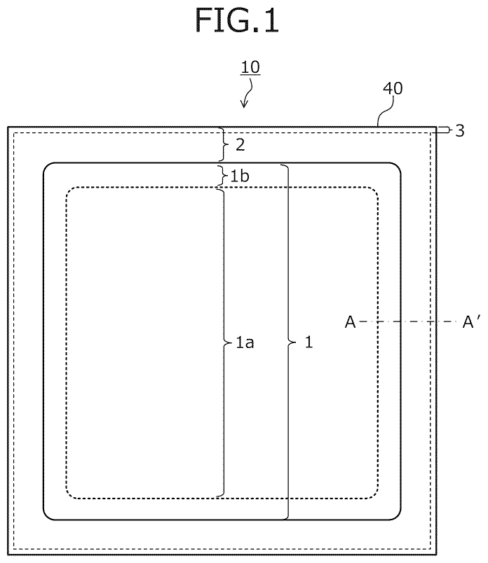

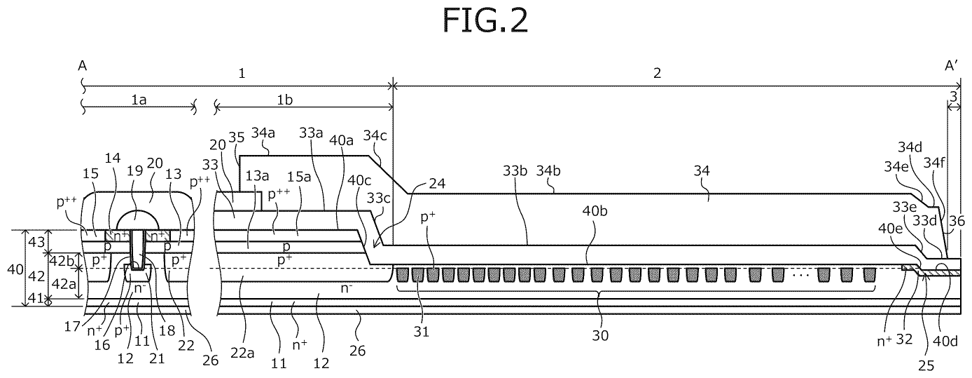

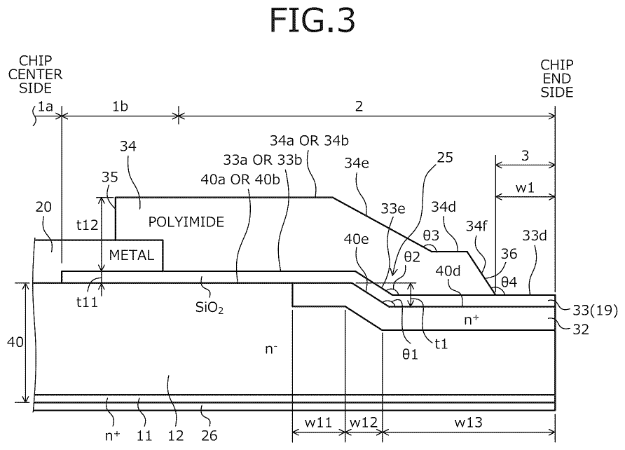

A semiconductor device according to a first embodiment solving the problems above is described. FIG. 1 is a plan view depicting a layout when the semiconductor device according to the embodiment is viewed from a front surface of a semiconductor substrate thereof. FIG. 2 is a cross-sectional view depicting a structure along cutting line A-A′ in FIG. 1. FIG. 3 is an enlarged view a cross-sectional view of a vicinity of a chip end in FIG. 2. In FIG. 3, to clearly depict the structure near the chip end, the structure closer to a chip center than is a channel stopper region 32 is depicted in a simplified manner or omitted and a length (length in a horizontal direction from the chip center to the chip end) of an edge termination region 2 is depicted in a different scale from that in FIG. 2.

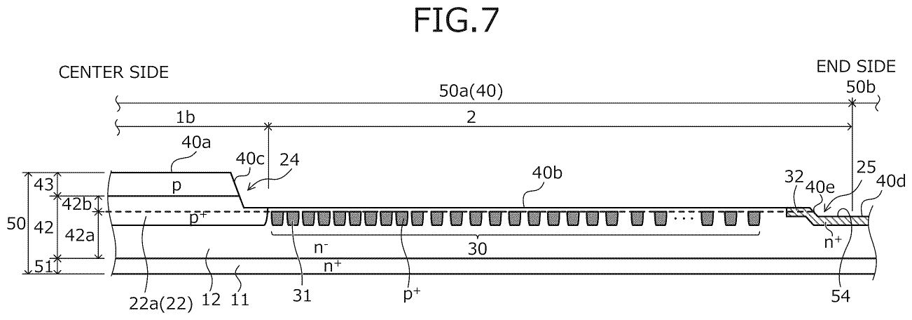

A semiconductor device 10 according to the embodiment depicted in FIGS. 1 to 3 has, in an outer peripheral portion including a scribe region 3 (remaining portions of scribe lines 50b of the semiconductor wafer 50, refer to later-described FIG. 7) of a semiconductor substrate (semiconductor chip) 40, a step (hereinafter, outer peripheral step) 25 along the outer periphery (the chip end) of the semiconductor substrate 40, the step 25 being formed by the front surface of the semiconductor substrate 40 being recessed. As a material of the semiconductor substrate 40, a semiconductor having a band gap wider than that of silicon (Si) (hereinafter, wide band gap semiconductor) such as silicon carbide (SiC) or gallium nitride (GaN) may be used. The material of the semiconductor substrate 40 may be Si.

As depicted in FIG. 1, the semiconductor substrate 40 has an active region 1 and the edge termination region 2. The active region 1 has a substantially rectangular shape in a plan view and is provided in substantially a center of the semiconductor substrate 40 (the chip center). The active region 1 is a portion inward (toward a chip center) from an outer peripheral end of a later-described p⁺-type outer peripheral region 22a. In a center portion 1a of the active region 1, cells (functional units of a device) each having a same structure are disposed connected in parallel. The center portion 1a of the active region 1, for example, is a region that has a substantially rectangular shape in a plan view and through which a main current (drift current) flows when the semiconductor device 10 is on. An outer peripheral region 1b of the active region 1 surrounds the center portion 1a of the active region 1 in a substantially rectangular shape in a plan view.

In the outer peripheral region 1b of the active region 1, for example, a circuit portion for protecting/controlling a device disposed in the center portion 1a of the active region 1 and a wiring layer (not depicted), etc. may be disposed. In an instance in which the semiconductor device 10 is a metal oxide semiconductor field effect transistor (MOSFET) having insulated gates with a three-layer metal-oxide-semiconductor structure or an insulated gate bipolar transistor (IGBT), a gate pad, a gate finger, etc. (not depicted) are disposed in the outer peripheral region 1b of the active region 1.

The edge termination region 2 is a region between the active region 1 and the chip end and surrounds the active region 1 in a substantially rectangular shape in a plan view. The edge termination region 2 has a function of relaxing electric field of a front side of the semiconductor substrate 40 and sustaining a breakdown voltage. In the edge termination region, for example, a predetermined voltage withstanding structure 30 such as a guard ring or a field limiting ring (FLR), junction termination extension (JTE) structure (refer to FIG. 2) is disposed. The breakdown voltage is an upper limit operating voltage at which malfunction or destruction of the semiconductor device 10 does not occur.

The edge termination region 2 has the scribe region 3 in an entire periphery of the semiconductor substrate 40. The scribe region 3 is a remaining portion of a cut margin (scribe lines 50b of the semiconductor wafer 50: see FIG. 7) when individual semiconductor chips (the semiconductor substrate 40) are cut from the semiconductor wafer 50 using a dicing blade or the like. A width of each of the scribe lines 50b of the semiconductor wafer 50, for example, is about 100 μm or about few tens of μm wider, and a blade width of a typical dicing blade, for example, is about 60 μm. A width w1 of the scribe region 3 of the semiconductor substrate 40 is, for example, about 20 μm from the chip end in a direction to the chip center. An alignment mark or a pattern for process monitoring, etc. may be formed in the scribe region 3, in a chip end side thereof. The chip end side of the scribe region 3 may be a portion free of an insulating layer 33 and the channel stopper region 32 due to the pattern for process monitoring or the alignment mark.

As depicted in FIGS. 2 and 3, the semiconductor substrate 40, for example, is formed by sequentially growing by epitaxy epitaxial layers 42, 43 on a front surface an n⁺-type starting substrate 41 (bulk substrate) 41 containing a wide band gap semiconductor. The semiconductor substrate 40 has, as the front surface, a first main surface having the epitaxial layer 43 and, as a back surface, a second main surface having the n⁺-type starting substrate 41. For example, in an instance in which the material of the semiconductor substrate 40 is Si, the semiconductor substrate 40 may be configured by the bulk substrate alone. Herein, as an example, an instance in which the material of the semiconductor substrate 40 is SiC and the semiconductor device 10, for example, is an n-channel-type MOSFET having a trench gate structure is described.

The n⁺-type starting substrate 41 constitutes an n⁺-type drain region 11. The epitaxial layers 42, 43 constitute an n⁻-type drift region 12 and a p-type base 13. In an instance in which the epitaxial layer 43 is a p-type, a portion of the epitaxial layer 43 in the edge termination region 2, for example, is removed by etching or the like and in a vicinity of the boundary of the edge termination region 2, a step (hereinafter, boundary step) 24 occurs at the front surface of the semiconductor substrate 40. The front surface of the semiconductor substrate 40 has a portion (hereinafter, first surface portion (second portion)) 40a in the active region 1 and a portion (hereinafter, second portion) 40b in the edge termination region 2 separated from each other with the boundary step 24 as a border, the second surface portion 40b being recessed closer to the n⁺-type drain region 11 than is the first surface portion 40a.

The front surface of the semiconductor substrate 4 has a portion (hereinafter, third surface portion) 40c connecting the first surface portion 40a and the second surface portion 40b, the third surface portion 40c may be vertical surface forming a substantially right angle with the second surface portion 40b of the front surface of the semiconductor substrate 40 or may be an inclined surface forming a tapered shape and obtuse angle with the second surface portion 40b. The second surface portion 40b of the front surface of the semiconductor substrate 40 is a surface of the epitaxial layer 42, which is of an n⁻-type and exposed when the boundary step 24 is formed. The boundary step 24 at the front surface of the semiconductor substrate 40 surrounds a periphery of the active region 1 in a plan view. The third surface portion 40c of the front surface of the semiconductor substrate 40 is a side surface (exposed surface) of the epitaxial layer 43 exposed when the boundary step 24 is formed. The epitaxial layer 42 may be exposed at the third surface portion 40c of the front surface of the semiconductor substrate 40.

Further, in an outer peripheral portion of the semiconductor substrate 40, a surface layer at the second surface portion 40b of the front surface of the semiconductor substrate 40 (exposed surface of the epitaxial layer 42 in the edge termination region 2), for example, is partially removed by etching or the like, thereby forming an outer peripheral step 25 forming a tapered shape or a substantially right angle with the front surface of the semiconductor substrate 40. The outer peripheral step 25 of the front surface of the semiconductor substrate 40 surrounds a periphery of the voltage withstanding structure 30 in a plan view. The front surface of the semiconductor substrate 40 has a portion (hereinafter, fourth surface portion (first portion)) 40d that is closer to the chip end than is the second surface portion 40b and is recessed closer to the n⁺-type drain region 11 than is the second surface portion 40b, the outer peripheral step 25 intervening between the fourth surface portion 40d and the second surface portion 40b as a border. The fourth surface portion 40d of the front surface of the semiconductor substrate 40 extends from the outer peripheral step 25 to the scribe region 3 and reaches the chip end. A thickness of the semiconductor substrate 40, at a portion thereof corresponding to the fourth surface portion 40d of the front surface of the semiconductor substrate 40, may be slightly reduced or inclined so as to gradually decrease in a direction to the chip end.

The front surface of the semiconductor substrate 40 has a portion (hereinafter, fifth surface portion (third portion)) 40e connecting the second surface portion 40b and the fourth surface portion 40d, the fifth surface portion 40e may be a vertical surface forming a substantially right angle with the fourth surface portion 40d of the front surface of the semiconductor substrate 40 or may be an inclined surface forming a tapered shape and obtuse angle with the fourth surface portion 40d. In particular, an angle of incline of the fifth surface portion 40e with respect to an extension line of the second surface portion 40b of the front surface of the semiconductor substrate 40 (hereinafter, simply, incline angle of the fifth surface portion 40e (angle of incline of the outer peripheral step 25)), for example, may be preferably 45 degrees or more but not more than about 90 degrees. As a result, formation of the outer peripheral step 25 of the front surface of the semiconductor substrate 40 is facilitated. The incline angle of the fifth surface portion 40e of the front surface of the semiconductor substrate 40 is an angle that is a difference obtained by subtracting an angle θ1 formed by the fifth surface portion 40e of the front surface of the semiconductor substrate 40 and the fourth surface portion 40d of the front surface of the semiconductor substrate 40 from a horizontal plane (=180 degrees).

The outer peripheral step 25 of the front surface of the semiconductor substrate 40 (i.e., the fourth surface portion 40d, the fifth surface portion 40e) is formed on the later-described channel stopper region 32 in the outer peripheral portion that includes the scribe region 3 and is positioned closer to the chip end than is an inner peripheral end of the channel stopper region 32. The fifth surface portion 40e of the front surface of the semiconductor substrate 40 may be formed in the scribe region 3. The outer peripheral step 25 of the front surface of the semiconductor substrate 40 is formed in the outer peripheral portion, which includes the scribe region 3 of the semiconductor substrate 40, and thus, the chip area (surface area of the semiconductor substrate 40) does not increase and operation of the semiconductor device 10 and function of the voltage withstanding structure 30 are not adversely affected by the outer peripheral step 25. A height difference (difference in thickness of the semiconductor substrate 40) t1 between the second surface portion 40b and the fourth surface portion 40d due to the outer peripheral step 25 of the front surface of the semiconductor substrate 40, for example, is about 0.5 μm or more but less than 5.0 μm.

The outer peripheral step 25 of the front surface of the semiconductor substrate 40, for example, is formed before or after the channel stopper region 32 is formed (i.e., selective ion implantation to the exposed surface of the epitaxial layer 42 for forming the channel stopper region 32) after the boundary step 24 is formed at the front surface of the semiconductor substrate 40 (i.e., after a portion of the epitaxial layer 43 in the edge termination region 2 is removed and the epitaxial layer 42 constituting the second surface portion 40b of the front surface of the semiconductor substrate 40 is exposed). The outer peripheral step 25 of the front surface of the semiconductor substrate 40, for example, may be formed concurrently with later-described trenches 16.

The boundary step 24 of the front surface of the semiconductor substrate 40 may be omitted (refer to FIG. 3). An instance in which the boundary step 24 of the front surface of the semiconductor substrate 40 is omitted, for example, is an instance in which, as an uppermost surface layer of the semiconductor substrate 40, the epitaxial layer 43 of an n-type or an n⁻-type is formed by epitaxy, or an instance in which the semiconductor substrate 40 is an n⁻-type bulk substrate. In an instance in which the boundary step 24 of the front surface of the semiconductor substrate 40 is omitted, at the front surface of the semiconductor substrate 40, the second surface portion 40b and the third surface portion 40c are not formed, the first surface portion 40a reaches the later-described channel stopper region 32 from the active region 1 and is connected to the fourth surface portion 40d by the fifth surface portion 40e.

In the semiconductor substrate 40, at the first surface portion 40a of the front surface thereof, a trench gate structure is provided in the center portion 1a of the active region 1, the trench gate structure including the p-type base 13, n⁺-type source regions 14, p⁺⁺-type contact regions 15, the trenches 16, gate insulating films 17, and gate electrodes 18. The n⁻-type drift region 12 is a portion of the n⁻-type epitaxial layer 42 excluding later-described first and second p⁺-type regions 21, 22, n-type current spreading regions (not depicted), FLRs 31, and the channel stopper region 32, the portion being between the n⁺-type starting substrate 41 and these regions, in contact with the regions, and provided in the active region 1 and the edge termination region 2.

The p-type base 13 is a portion of the p-type epitaxial layer 43 excluding the n⁺-type source regions 14 and the p⁺⁺-type contact regions 15. The p-type base 13 is provided in an entire region between the first surface portion 40a of the front surface of the semiconductor substrate 40 and the n⁻-type drift region 12. The n⁺-type source regions 14 and the p⁺⁺-type contact regions 15 are diffused regions selectively formed by ion implantation in the epitaxial layer 43. The n⁺-type source regions 14 and the p⁺⁺-type contact regions 15 are each selectively provided between the first surface portion 40a of the front surface of the semiconductor substrate 40 and the p-type base 13 and are in contact with the p-type base 13.

The n⁺-type source regions 14 and the p⁺⁺-type contact regions 15 are in contact with a source electrode 20 at the first surface portion 40a of the front surface of the semiconductor substrate 40. The p⁺⁺-type contact regions 15 may be omitted. In this instance, instead of the p⁺⁺-type contact regions 15, the p-type base 13 is exposed at the first surface portion 40a of the front surface of the semiconductor substrate 40. As an uppermost layer of the semiconductor substrate 40, when the epitaxial layer 43 of an n-type or an n⁻-type is formed by epitaxy or when the semiconductor substrate 40 is an n⁻-type bulk substrate, the p-type base 13 is selectively formed by ion implantation in the epitaxial layer 43.

Between the n⁻-type drift region 12 and the p-type base 13, the p⁺-type regions 21, 22 and the n-type current spreading regions may be provided at deep positions closer to the n⁺-type drain region 11 than are bottoms of the trenches 16. The p⁺-type regions 21, 22 have a function of relaxing electric field applied to the bottoms of the trenches 16. The p⁺-type regions 21 are provided apart from the p-type base 13 and face the bottoms of the trenches 16 in a depth direction. The p⁺-type regions 21 are fixed to the potential of the source electrode 20 at a non-depicted portion. The p⁺-type regions 21, for example, are selectively formed in the epitaxial layer 42 (42a) concurrently with lower portions of the p⁺-type regions 22.

The p⁺-type regions 22 are provided between the trenches 16, the p⁺-type regions 22 being apart from the p⁺-type regions 21 and the trenches 16, and in contact with the p-type base 13. For example, for each stage of epitaxial growth of the n⁻-type epitaxial layer 42 (42a, 42b) constituting the n⁻-type drift region 12, ion-implantation of a p-type dopant in the formed epitaxial sublayer 42a, 42b is performed, thereby forming the p⁺-type regions 22. The p⁺-type regions (upper portion and lower portion of each the p⁺-type regions 22) selectively formed in each of the epitaxial sublayers 42a, 42b are connected to each other, thereby forming each of the p⁺-type regions 22.

The n-type current spreading regions constitute a so-called current spreading layer that lower carrier spreading resistance. The n-type current spreading regions are provided between the p⁺-type regions 21, 22 that are adjacent to each other, and are in contact with the p-type base 13 and the n⁻-type drift region 12. The n-type current spreading regions are in contact with the trenches 16, between the p-type base 13 and the p⁺-type regions 21. In an instance in which the n-type current spreading regions are omitted, the n⁻-type drift region 12 extends between the p-type base 13 and the p⁺-type regions 21 and the trenches 16, from between the p⁺-type regions 21, 22 that are adjacent to each other.

The trenches 16 penetrate through the n⁺-type source regions 14 and the p-type base 13 in the depth direction from the first surface portion 40a of the front surface of the semiconductor substrate 40 and terminate in the n⁻-type drift region 12 (in an instance in which the n-type current spreading regions are provided, the n-type current spreading regions) or the trenches 16 terminate in the p⁺-type regions 21. Inside the trenches 16, the gate electrodes 18 are provided via the gate insulating films 17. An insulating film 19 is provided in an entire area of the front surface of the semiconductor substrate 40 and covers the gate electrodes 18. The insulating film 19, for example, is a silicon oxide (SiO₂) film such as borophosphosilicate glass (BPSG).

The source electrode 20 is provided on the insulating film 19, in an entire area of the center portion 1a of the active region 1. The source electrode 20 is in ohmic contact with the n⁺-type source regions 14 and the p⁺⁺-type contact regions 15 through contact holes of the insulating film 19 and is electrically connected to these regions and the p-type base 13. The source electrode 20 may extend outward (toward the chip end) on the insulating film 19 and terminate at the outer peripheral region 1b of the active region 1. A drain electrode 26 is provided in an entire area of a back surface of the semiconductor substrate 40 (back surface of the n⁺-type starting substrate 41) and is electrically connected to the n⁺-type drain region 11 (the n⁺-type starting substrate 41).

In the outer peripheral region 1b of the active region 1, a p-type outer peripheral region is provided in an entire area between the first surface portion 40a of the front surface of the semiconductor substrate 40 and the n⁻-type drift region 12. The p-type outer peripheral region is formed by the p⁺-type outer peripheral region 22a, a p-type base extension portion 13a, and a p⁺⁺-type outer peripheral contact region 15a stacked sequentially in the order stated from the n⁻-type drift region 12 side; the p-type outer peripheral region surrounds a periphery of the center portion 1a of the active region 1 in a substantially rectangular shape, in a plan view. The p⁺-type outer peripheral region 22a and the p⁺⁺-type outer peripheral contact region 15a are formed concurrently with the p⁺-type regions 22 and the p⁺⁺-type contact regions 15, respectively. The p-type base extension portion 13a is an outer peripheral portion of the p-type base 13.

The p⁺-type outer peripheral region 22a, the p-type base extension portion 13a, and the p⁺⁺-type outer peripheral contact region 15a are electrically connected to the source electrode 20 at an undepicted portion, via the p⁺⁺-type outer peripheral contact region 15a (in an instance in which the p⁺⁺-type outer peripheral contact region 15a is omitted, the p-type base extension portion 13a). The p⁺-type outer peripheral region 22a, the p-type base extension portion 13a, and the p⁺⁺-type outer peripheral contact region 15a reach the third surface portion 40c of the front surface of the semiconductor substrate 40. The p⁺-type outer peripheral region 22a extends outwardly closer to the chip end than is the boundary step 24 along the third surface portion 40c of the front surface of the semiconductor substrate 40, and reaches the second surface portion 40b of the front surface of the semiconductor substrate 40.

In the edge termination region 2, p⁺-type regions 31 (portions indicated by dotted hatching) configuring the voltage withstanding structure 30 are selectively provided between the second surface portion 40b of the front surface of the semiconductor substrate 40 (in an instance in which the boundary step 24, the first surface portion 40a) and the n⁻-type drift region 12. The voltage withstanding structure 30, for example, may be a FLR structure, a spatial modulation JTE structure, or a multi-zone JTE structure mainly disposed in an instance in which a material of the semiconductor substrate 40 is SiC (in FIG. 2, a FLR structure is depicted). The multi-zone JTE structure is a structure in which three or more p-type regions fixed to the potential of the source electrode 20 are disposed adjacent to each other in concentric shapes surrounding the periphery of the active region in a plan view, the three or more p-type regions being arranged in descending order of dopant concentration in a direction from the active region to the chip end.

The spatial modulation JTE structure is an improved JTE structure in which between adjacent p-type regions, a p-type spatial modulation region disposed adjacent to these two p-type regions has a dopant concentration distribution spatially equivalent to an intermediate dopant concentration of the two adjacent p-type regions and a dopant concentration distribution of the overall JTE structure gradually decreases outwardly in a direction to the chip end. The spatial modulation region is formed by alternately and repeatedly disposing in a predetermined pattern, in concentric shapes surrounding the periphery of the active region 1, two p-type subregions of a same dopant concentration as that of p-type regions adjacent thereto on both sides. The FLR structure is a structure also called a guard ring structure, in which the p⁺-type regions 31 (FLRs) of a same dopant concentration and with a floating potential are disposed apart from each other in concentric shapes surrounding the periphery of the active region 1 in a plan view.

In the edge termination region 2, in an entire region between the n⁻-type drift region 12 and the fourth surface portion 40d and the fifth surface portion 40e of the front surface of the semiconductor substrate 40, the channel stopper region 32 (portion indicated by diagonal line hatching) is provided in the semiconductor substrate 40, along the fourth surface portion 40d and the fifth surface portion 40e of the front surface. The channel stopper region 32 is provided apart from the voltage withstanding structure 30 and closer to the chip end than is the voltage withstanding structure 30; the channel stopper region 32 surrounds the periphery of the voltage withstanding structure 30 in a plan view. The channel stopper region 32, for example, may be an n⁺-type region formed concurrently with the n⁺-type source regions 14 or, for example, may be a p⁺-type region (not depicted) formed concurrently with the p⁺-type regions 21, 22. The channel stopper region 32 is bordered by the n⁻-type drift region 12. Between the channel stopper region 32 and an outermost one of the p⁺-type regions 31, the n⁻-type drift region 12 reaches the front surface of the semiconductor substrate 40. The channel stopper region 32 is exposed at the fourth surface portion 40d of the front surface of the semiconductor substrate 40, the fifth surface portion 40e, and the chip end. Along the front surface of the semiconductor substrate 40, the channel stopper region 32 extends along the outer peripheral step 25 from the fourth surface portion 40d and the fifth surface portion 40e and is exposed at the second surface portion 40b of the front surface of the semiconductor substrate 40 (in an instance in which the boundary step 24 is not provided, the first surface portion 40a).

Preferably, the inner peripheral end of the channel stopper region 32 may be positioned at substantially a same depth as a depth of p-type regions (the p⁺-type regions 21, 22, the p⁺-type outer peripheral region 22a) forming main junctions (pn junctions) of the active region 1 and the p⁺-type regions 31 configuring the voltage withstanding structure 30. The channel stopper region 32 has a function of suppressing a depletion layer from reaching the chip end, the depletion layer spreading from the main junctions of the active region 1 and pn junctions formed by the p⁺-type regions 31 of the voltage withstanding structure 30 when the semiconductor device 10 is off, and a function of suppressing a concentration of electric field at the outer peripheral step 25 of the front surface of the semiconductor substrate 40. No field plate or channel stopper electrode are provided and the channel stopper region 32 has a floating potential.

A portion of the channel stopper region 32 extends closer to the chip center than is the outer peripheral step 25 of the front surface of the semiconductor substrate 40 and has a width w11 of, for example, about 10 μm. A portion of the channel stopper region 32 faces the fifth surface portion 40e of the front surface of the semiconductor substrate 40 in a vertical direction (direction orthogonal to the horizontal direction, which is a direction from the chip center to the chip end) and has a width (width in the horizontal direction, which is a direction from the chip center to the chip end) w12 that differs depending on the incline angle of the fifth surface portion 40e. A portion of the channel stopper region 32 faces the fourth surface portion 40d of the front surface of the semiconductor substrate 40 in the vertical direction and has a width w13 that is equal to a width of the fourth surface portion 40d of the front surface of the semiconductor substrate 40 and, for example, is about 40 μm or more but less than 50 μm.

An entire area of the first surface portion 40a to the fifth surface portion 40e of the front surface of the semiconductor substrate 40 in the outer peripheral region 1b of the active region 1 and the edge termination region 2 is covered by the insulating layer 33. The insulating layer 33 may be a single layer structure formed by the insulating film 19 (FIG. 2) or may be stacked structure including a field oxide film, the gate insulating films 17, and the insulating film 19 (not depicted). A thickness t11 of the insulating layer 33 is constant in the entire area of the front surface of the semiconductor substrate 40. Thus, at an upper surface of the insulating layer 33, at portions above the steps 24, 25 of the front surface of the semiconductor substrate 40, steps of substantially same height differences, respectively, as those of the steps 24, 25 are formed.

In other words, the first surface portion 40a to the fifth surface portion 40e of the front surface of the semiconductor substrate 40 and a first upper surface portion 33a, a second upper surface portion 33b, a third upper surface portion 33c, a fourth upper surface portion 33d, and a fifth upper surface portion 33e of the insulating layer 33 provided, respectively, on the first surface portion 40a to the fifth surface portion 40e are substantially parallel to each other, respectively. An incline angle of the fifth upper surface portion 33e (hereinafter, simply, incline angle of the fifth upper surface portion 33e) with respect to an extension line of the second upper surface portion 33b of the insulating layer 33 is substantially a same as the incline angle of the fifth surface portion 40e of the front surface of the semiconductor substrate 40 (=180 degrees−θ1). The incline angle of the fifth upper surface portion 33e of the insulating layer 33 is an angle that is a difference obtained by subtracting an angle θ2 formed by the fifth upper surface portion 33e of the insulating layer 33 and the fourth upper surface portion 33d of the insulating layer 33 from the horizontal plane (180 degrees) (=180 degrees−θ2).

A surface protective film 34 containing a polyimide is provided at an upper most surface of the front surface of the semiconductor substrate 40. An entire area of the front surface of the semiconductor substrate 40 excluding an electrode pad and the scribe region 3 is covered by the surface protective film 34. In the scribe region 3, at an uppermost surface of the front surface of the semiconductor substrate 40 is the insulating layer 33. A portion of the source electrode 20 exposed in an opening 35 of the surface protective film 34 functions as a source pad (electrode pad). The surface protective film 34 is provided on the insulating layer 33 in the outer peripheral region 1b of the active region 1 and the edge termination region 2 and covers the steps 24, 25 of the front surface of the semiconductor substrate 40 via the insulating layer 33.

At an upper surface of the surface protective film 34, at portions above the steps 24, 25 of the front surface of the semiconductor substrate 40, steps of height differences different from those of the steps 24, 25 are formed. The first surface portion 40a, the second surface portion 40b, and the fourth surface portion 40d of the front surface of the semiconductor substrate 40 are respectively parallel to a first upper surface portion 34a, a second upper surface portion 34b, and a fourth upper surface portion 34d of the surface protective film 34 on the first surface portion 40a, the second surface portion 40b, and the fourth surface portion 40d. The surface protective film 34 has a portion above the first surface portion 40a and the second surface portion 40b of the front surface of the semiconductor substrate 40 with, for example, a constant thickness t12 of about 10 μm, while at portions of the surface protective film 34 where the upper surface thereof is inclined (portions of a third upper surface portion 34c, a fifth upper surface portion 34e, and a later-described outer end surface portion 34e), the thickness t12 varies according to the incline angle.

Of the surface protective film 34, the third upper surface portion 34c connecting the first upper surface portion 34a and the second upper surface portion 34b is positioned above the third surface portion 40c of the front surface of the semiconductor substrate 40. The incline angle of the third upper surface portion 34c with respect to an extension line of the first upper surface portion 34a of the surface protective film 34 is gradual and slightly smaller than the incline angle of the third surface portion 40c of the front surface of the semiconductor substrate 40. Of the surface protective film 34, the fifth upper surface portion 34e connecting the second upper surface portion 34b and the fourth upper surface portion 34d is positioned above the fifth surface portion 40e of the front surface of the semiconductor substrate 40. The incline angle of the fifth upper surface portion 34e with respect to an extension line of the second upper surface portion 34b of the surface protective film 34 (hereinafter, simply, the incline angle of the fifth upper surface portion 34e) is gradual and slightly smaller than the incline angle of the fifth surface portion 40e of the front surface of the semiconductor substrate 40. The incline angle of the fifth upper surface portion 34e of the surface protective film 34 is a difference obtained by subtracting an angle θ3 formed by the fifth upper surface portion 34e of the surface protective film 34 and the fourth upper surface portion 34d of the surface protective film 34 from the horizontal plane (=180 degrees−θ3).

The second upper surface portion 34b of the surface protective film 34 is inclined even when the fifth surface portion 40e of the front surface of the semiconductor substrate 40 is substantially vertical. An outer peripheral end of the surface protective film 34 terminates at an inner peripheral end of the scribe region 3 and does not reach the chip end. A reason for this is that the portion of the surface protective film 34 covering the scribe lines 50b of the semiconductor wafer 50 is removed before dicing of the semiconductor wafer (cutting individual semiconductor chips (the semiconductor substrates 40) from the semiconductor wafer 50). As a result, during dicing of the semiconductor wafer, the scattering of processing debris (polyimide) of the surface protective film 34 caused by the dicing blade, etc. may be prevented. Further, the structure is free of a protective metal film that extends to the chip end of the semiconductor substrate 40 like the protective metal film depicted in FIG. 7 of Japanese Patent No. 7085959 and thus, no scattering of metal debris caused by dicing blades, etc. occurs during dicing of the semiconductor wafer.

An outer end surface portion (side surface) 34f connecting the outer peripheral end of the surface protective film 34 and the fourth upper surface portion 34d is an inclined surface forming a tapered shape and obtuse angle with the fourth upper surface portion 33d of the insulating layer 33. The incline angle of the outer end surface portion 34e with respect to an extension line of the fourth upper surface portion 34d of the surface protective film 34 (hereinafter, simply, incline angle of the outer end surface portion 34e) may be steeper and larger than the incline angle of the fifth surface portion 40e of the front surface of the semiconductor substrate 40. The incline angle of the outer end surface portion 34e of the surface protective film 34 is an angle that is a difference obtained by subtracting an angle θ4 formed by the outer end surface portion 34e of the surface protective film 34 and the fourth upper surface portion 33d of the insulating layer 33 in the scribe region 3 from the horizontal plane (=180 degrees−θ4).

In other words, the surface protective film 34 covers the voltage withstanding structure 30 and the outer peripheral step 25 of the front surface of the semiconductor substrate 40, via the insulating layer 33. The surface protective film 34 covers the channel stopper region 32, excluding the scribe region 3, via the insulating layer 33. The surface protection film 34 has a tapered inclined surface (more specifically, the fifth upper surface portion 34e and the outer end surface portion 34e) that faces, in the depth direction, a portion (the fourth surface portion 40d and the fifth surface portion 40e of the front surface of the semiconductor substrate 40) that is relatively recessed toward the n⁺ type drain region 11 due to the outer peripheral step 25 at the front surface of the semiconductor substrate 40, and is inclined at an incline angle of less than 90 degrees with respect to the first upper surface 34a and the second upper surface 34b.

The outer peripheral end of the surface protective film 34 is positioned above the fifth surface portion 40e (portion recessed toward the n⁺-type drain region 11) of the front surface of the semiconductor substrate 40 and thus, even when moisture (water vapor) in the air flows in from the outer peripheral end of the surface protective film 34 and flows along the interface between the surface protective film 34 and the insulating layer 33 in a direction to the chip center, an intrusion of the moisture from the outer peripheral step 25 of the front surface of the semiconductor substrate 40 may be suppressed. Thus, the moisture resistance of the semiconductor device 10 may be improved. A surface layer at the front surface of the semiconductor substrate 40 is locally removed, whereby the outer peripheral step 25 may be easily formed at the front surface of the semiconductor substrate 40, thereby enabling increases in cost to be suppressed.

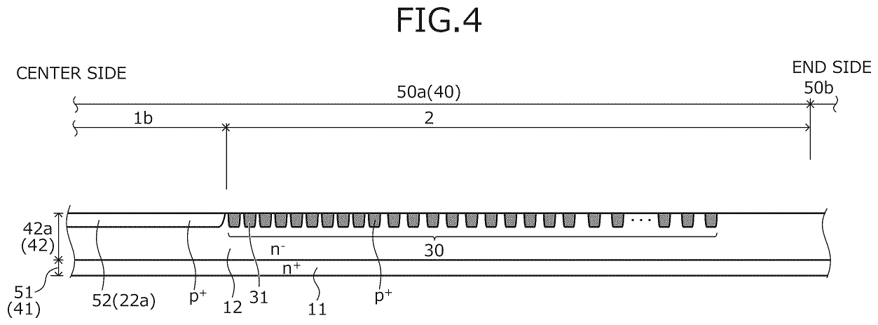

A method of manufacturing the semiconductor device 10 according to the first embodiment is described. FIGS. 4, 5, 6, and 7 are cross-sectional views depicting states of the semiconductor device according to the first embodiment during manufacture. In FIGS. 4 to 7, only the outer peripheral region 1b of the active region 1 and the edge termination region 2 (refer to FIG. 2) of only one of multiple chip regions 50a are depicted and the center portion 1a of the active region 1 is described with reference to FIG. 2. Each of the chip regions 50a is a region constituting a semiconductor chip (the semiconductor substrate 40) cut from the semiconductor wafer 50 along the scribe lines 50b by a dicing blade or the like.

First, as depicted in FIG. 4, at a front surface of an n⁺-type starting wafer 51 constituting the n⁺-type starting substrate 41, the n⁻-type epitaxial layer 42a constituting the n⁻-type drift region 12 is formed by epitaxy. Next, by photolithography and ion-implantation of a p-type dopant, for example, the p⁺-type regions 21, lower portions of the p⁺-type regions 22, a lower portion 52 of the p⁺-type outer peripheral region 22a, and the p⁺-type regions 31 of the voltage withstanding structure 30 are each selectively formed in surface regions of the epitaxial layer 42a, using a same ion-implantation mask.

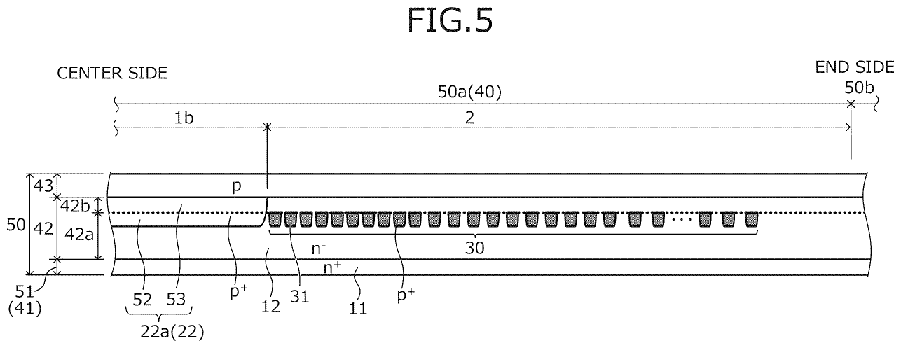

Next, as depicted in FIG. 5, the n⁻-type epitaxial layer 42b is further formed on the epitaxial layer 42a by epitaxy, thereby increasing the thickness and forming the epitaxial layer 42 (42a, 42b) of a product (the semiconductor device 10) thickness. Next, by photolithography and ion-implantation of a p-type dopant, upper portions of the p⁺-type regions 22 and an upper portion 53 of the p⁺-type outer peripheral region 22a are formed in the epitaxial layer 42b and in the depth direction, are respectively connected to the lower portions of the p⁺-type regions 22 and the lower portion 52 of the p⁺-type outer peripheral region 22a.

At this time, ion implantation is not performed in the epitaxial layer 42b in the edge termination region 2 and thus, all the p⁺-type regions 31 may be covered by the n⁻-type epitaxial layer 42b left as the n⁻-type drift region 12. Alternatively, the thickness of each of the p⁺-type regions 31 may be increased by selectively ion-implanting a p-type dopant in the epitaxial layer 42b in the edge termination region 2, concurrently with formation the upper portions of the p⁺-type regions 22 and the upper portion 53 of the p⁺-type outer peripheral region 22a (not depicted).

Next, at the surface of the epitaxial layer 42, the p-type epitaxial layer 43 constituting the p-type base 13 is formed by epitaxy. By the processes up to here, the semiconductor wafer 50 in which the epitaxial layers 42, 43 constituting the n⁻-type drift region 12 and the p-type base 13 are formed sequentially on the n⁺-type starting wafer 51 is completed.

When the n⁻-type epitaxial layers 42a, 42b constituting the n⁻-type drift region 12 are formed by epitaxy, the lower portions and the upper portions of the n-type current spreading regions may be respectively formed in the epitaxial layers 42a, 42b, in an entire area of the active region 1, by photolithography and ion-implantation of an n-type dopant so as to be connected in the depth direction.

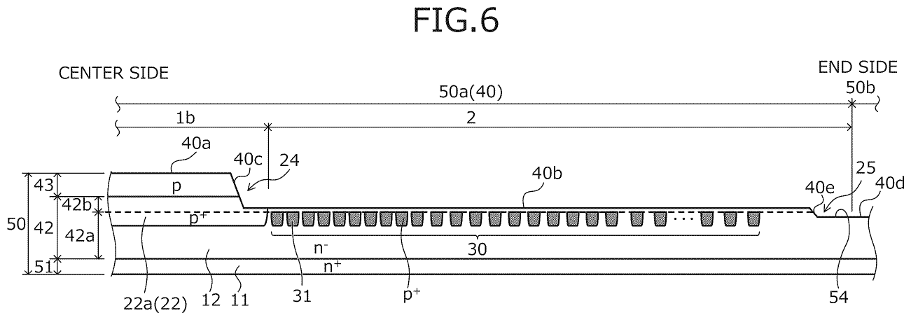

Next, as depicted in FIG. 6, by photolithography and etching, the portion of the epitaxial layer 43 in the edge termination region 2 is removed and the p-type epitaxial layer 43 is left only in the active region 1. As a result, in each of the chip regions 50a of the semiconductor wafer 50, at the front surface of the semiconductor wafer 50, the boundary step 24 where an outer portion (the second surface portion 40b) of the chip region 50a is closer to (recessed toward) the n⁺-type starting wafer 51 than is a center portion (the first surface portion 40a) of the chip region 50a is formed.

In the edge termination region 2 of each of the chip regions 50a of the semiconductor wafer 50, the n⁻-type epitaxial layer 42b is exposed at the front surface (the second surface portion 40b) of the semiconductor wafer 50. The periphery of each of the chip regions 50a of the semiconductor wafer 50 is bordered by the scribe lines 50b. For example, in the semiconductor wafer 50, the chip regions 50a are disposed in a matrix-like pattern and the scribe lines 50b are formed in a grid-like pattern bordering the peripheries of all the chip regions 50a.

Next, as depicted in FIG. 7, by photolithography and etching, a surface layer of the epitaxial layer 42 at the scribe lines 50b of the semiconductor wafer 50 is removed, whereby recesses 54 are formed in a grid-like pattern bordering the peripheries of the chip regions 50a. At this time, a width of each of the recesses 54 is wider than the width of each of the scribe lines 50b, whereby the surface layer of the epitaxial layer 42 in the outer peripheral portion of each of the chip regions 50a is also removed.

As a result, in each of the chip regions 50a of the semiconductor wafer 50, at the front surface of the semiconductor wafer 50, the outer peripheral step 25 where the outer peripheral portion (the fourth surface portion 40d) of each of the chip regions 50a is closer to (recessed toward) the n⁺-type starting wafer 51 than is the center portion (the second surface portion 40b) of each of the chip regions 50a is formed. In regions of all the scribe lines 50b, similar to the outer peripheries of the chip regions 50a, the surface of the semiconductor wafer 50 is also relatively closer to the n⁺-type starting wafer 51.

Next, by photolithography and ion implantation, in surface regions (surface regions of the p-type epitaxial layer 43) at the first surface portion 40a of the front surface of the semiconductor wafer 50, the n⁺-type source regions 14, the p⁺⁺-type contact regions 15, and the p⁺⁺-type outer peripheral contact region 15a are each selectively formed. By photolithography and ion implantation, the n⁺-type channel stopper region 32 is selectively formed in surface regions of the semiconductor wafer 50 (surface regions of the n⁻-type epitaxial layer 42), at the second surface portion 40b, the fourth surface portion 40d, and the fifth surface portion 40e of the front surface.

The channel stopper region 32 may formed across the chip regions 50a that are adjacent, or concurrently with the n⁺-type source regions 14. A portion of the n⁻-type epitaxial layer 42, excluding the p⁺-type regions 21, 22, the p⁺-type outer peripheral region 22a, the n-type current spreading regions, the p⁺-type regions 31, and the channel stopper region 32 constitutes the n⁻-type drift region 12. A portion of the p-type epitaxial layer 43, excluding the n⁺-type source regions 14, the p⁺⁺-type contact regions 15, and the p⁺⁺-type outer peripheral contact region 15a constitutes the p-type base 13.

Next, the ion-implanted dopants are activated by a heat treatment. Next, by a general method, the trenches 16, the gate insulating films 17, the gate electrodes 18, the insulating film 19, the source electrode 20, the drain electrode 26, and the surface protective film 34 are formed. Next, the opening 35 exposing a portion of the source electrode 20 constituting the electrode pad and an opening 36 exposing the scribe lines 50b and the outer peripheral portion of the chip regions 50a are formed in the surface protective film 34 by photolithography and etching.

Thereafter, the semiconductor wafer 50 is cut (diced) along the scribe lines 50b by a dicing blade or the like and the chip regions 50a of the semiconductor wafer 50 are diced into individual semiconductor chips (the semiconductor substrates 40). Along the entire outer periphery of each of the semiconductor substrates 40, the scribe lines 50b of the semiconductor wafer 50 are partially left as the scribe region 3. A sidewall of the opening 36 of the surface protective film 34 constitutes the outer end surface portion 34e of the surface protective film 34. Thus, the semiconductor device 10 depicted in FIGS. 1 to 3 is completed.

As described, according to the first embodiment, in the outer peripheral portion that includes scribe lines left along the outer periphery of the semiconductor substrate (semiconductor chip), the outer peripheral step is formed at the front surface of the semiconductor substrate. The surface protective film of the uppermost surface of the front surface of the semiconductor substrate covers the outer peripheral step of the front surface of the semiconductor substrate and terminates on the fourth surface portion (portion relatively recessed toward the n⁺-type drain region due to the outer peripheral step) of the front surface of the semiconductor substrate. As a result, even when moisture (water vapor) flows in from the outer peripheral end of the surface protective film and flows in a direction to the chip center along the surface protective film and the interface with the insulating layer therebelow, the moisture does not easily from the outer peripheral step of the front surface of the semiconductor substrate to the chip center. Therefore, moisture resistance of the semiconductor device may be improved and reliability of the semiconductor device may be improved.

Further, according to the first embodiment, the outer peripheral step (structure for improving moisture resistance) of the front surface of the semiconductor substrate is a simple structure and may be easily formed by etching or the like. In addition, an etching process for forming the outer peripheral step at the front surface of the semiconductor substrate may be easily added to an existing method of manufacturing a semiconductor device without complicating the manufacturing processes. Thus, increases in manufacturing costs may be suppressed. Further, the outer peripheral step of the front surface of the semiconductor substrate is formed in the outer peripheral portion that includes the scribe lines and thus, increases in the chip area may be suppressed and increases in product cost may be suppressed.

Therefore, a semiconductor device with improved moisture resistance may be easily fabricated (manufactured) while suppressing increases in cost and maintaining the chip area.

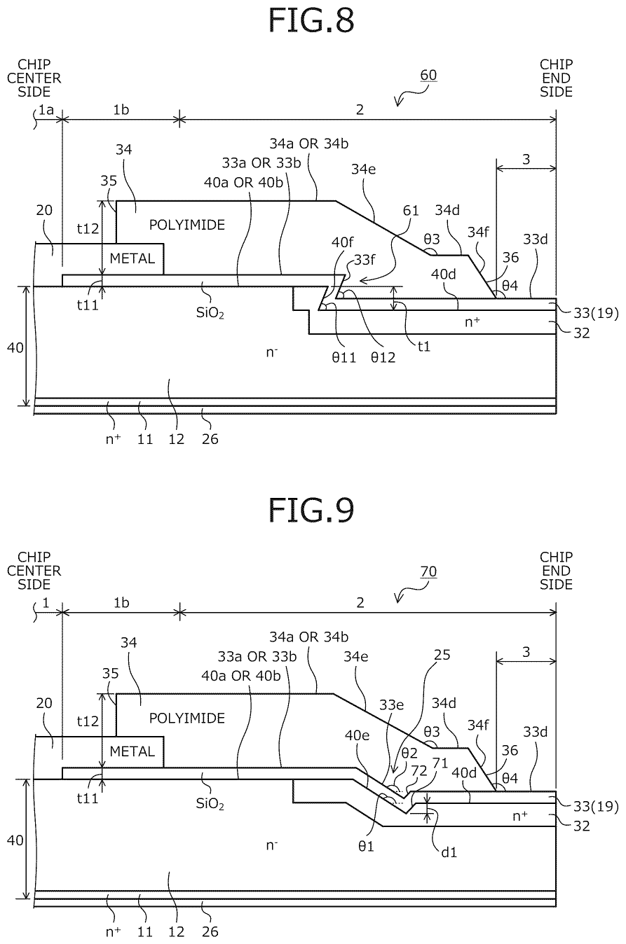

A semiconductor device according to a second embodiment solving the problems above is described. FIG. 8 is a cross-sectional view depicting a structure of a semiconductor device according to the second embodiment. A semiconductor device 60 according to the second embodiment differs from the semiconductor device 10 according to the first embodiment (refer to FIG. 3) in that at the front surface of the semiconductor substrate 40, an outer peripheral step 61 formed on the channel stopper region 32 forms a reverse tapered shape.

In the second embodiment, the front surface of the semiconductor substrate 40, with the outer peripheral step 61 as a border, is recessed toward the n⁺-type drain region 11 at the fourth surface portion 40d on the chip end side more than the second surface portion 40b (in an instance in which the boundary step 24 is not formed, the first surface portion 40a) on the chip center side. A portion of the front surface of the semiconductor substrate 40 connecting the second surface portion 40b and the fourth surface portion 40d to each other is a fifth surface portion (third portion) 40f that is a reverse taper inclined surface forming a sharp angle with the fourth surface portion 40d of the front surface of the semiconductor substrate 40.

The second surface portion 40b of the front surface of the semiconductor substrate 40 protrudes closer to the chip end than is a border between the fifth surface portion 40f and the fourth surface portion 40d of the front surface of the semiconductor substrate 40. An angle θ11 formed by the fifth surface portion 40f of the front surface of the semiconductor substrate 40 and the fourth surface portion 40d of the front surface of the semiconductor substrate 40 is an incline angle (incline angle of the outer peripheral step 61) of the fifth surface portion 40f with respect to the fourth surface portion 40d of the front surface of the semiconductor substrate 40 and, for example, is 45 degrees or more but less than 90 degrees.

The outer peripheral step 61 having a reverse tapered shape, for example, may be obtained by performing in the method of manufacturing the semiconductor device 10 according to the first embodiment, anisotropic etching capable of forming recesses with a roughly rectangular shape in a cross-sectional view as the etching for forming recesses (in FIG. 6, corresponds to the recesses 54 formed in the scribe lines 50b and the outer peripheral portions of each of the chip regions 50a of the semiconductor wafer 50) formed by removing the surface layer of the epitaxial layer 42 in the outer peripheral portion that includes the scribe region 3 of the semiconductor substrate 40.

Conditions of the anisotropic etching are suitably set, whereby a recess (recess having a trapezoidal shape that widens in the depth direction, in a cross-sectional view) having a sidewall with a reverse tapered shape may be formed at the front surface of the semiconductor substrate 40. In this instance, the angle θ11 formed by the fifth surface portion 40f of the front surface of the semiconductor substrate 40 and the fourth surface portion 40d of the front surface of the semiconductor substrate 40 is less than 90 degrees and an angle close to 90 degrees (for example, about 80 degrees or more) may be set.

The first surface portion 40a to the fifth surface portion 40f of the front surface of the semiconductor substrate 40 and the first upper surface portion 33a to a fifth upper surface portion 33f of the insulating layer 33 on the first surface portion 40a to the fifth surface portion 40f, similar to the first embodiment, are substantially parallel to each other respectively. An angle θ12 formed by the fifth upper surface portion 33f of the insulating layer 33 and the fourth upper surface portion 33d of the insulating layer 33 is substantially a same as the angle θ11 formed by the fifth surface portion 40f of the front surface of the semiconductor substrate 40 and the fourth surface portion 40d of the front surface of the semiconductor substrate 40.

Other than the reverse tapered shape of the outer peripheral step 61, the structure is a same as that of the outer peripheral step 25 of the first embodiment. In the semiconductor device 60 according to the second embodiment, other than the outer peripheral step 61 of the front surface of the semiconductor substrate 40 and the reverse-tapered fifth upper surface portion 33f of the insulating layer 33 thereon, the configuration is a same as that of the first embodiment. When a height difference t1 between the second surface portion 40b and the fourth surface portion 40d of the front surface of the semiconductor substrate 40 is about 1 μm or less, the incline angle of the fifth upper surface portion 34e of the surface protective film 34 is a same as that in the first embodiment.

As described, according to the second embodiment, an effect similar to that of the first embodiment may be obtained. Moisture that flows in from the outer peripheral end of the surface protective film and flows along the interface between the surface protective film and the insulating layer in a direction to the center of the chip remains within the reverse tapered outer peripheral step of the front surface of the semiconductor substrate and within the reverse tapered step on the top surface of the insulating layer above the outer peripheral step, whereby the moisture does not easily flow toward the center of the chip and thus, the effect of improving the moisture resistance of the semiconductor device is further enhanced.

A semiconductor device according to a third embodiment solving the problems above is described. FIG. 9 is a cross-sectional view depicting a structure of a semiconductor device according to the third embodiment. A semiconductor device 70 according to the third embodiment differs from the semiconductor device 10 according to the first embodiment (refer to FIG. 3) in that a sub-trench (groove) 71 is formed in a portion relatively recessed toward the n⁺-type drain region 11 due to the outer peripheral step 25 of the front surface of the semiconductor substrate 40.

In the third embodiment, a sub-trench 71 of a predetermined depth d1 from the fourth surface portion 40d is provided at the fourth surface portion 40d of the front surface of the semiconductor substrate 40. The sub-trench 71 surrounds the periphery of the voltage withstanding structure 30 in a plan view. The sub-trench 71 has a sidewall (on the chip center) that may be continuous with the fifth surface portion 40e of the front surface of the semiconductor substrate 40 or may disposed apart from the fifth surface portion 40e of the front surface of the semiconductor substrate 40 with the fourth surface portion 40d intervening between the sidewall and the fifth surface portion 40e.

The sub-trench 71, in a cross-sectional view, may have an inverted triangle shape, with the sidewalls inclined so that the width becomes narrower in the depth direction. In this instance, an incline angle of the sidewall of the sub-trench 71 with respect to the fourth surface portion 40d of the front surface of the semiconductor substrate 40 may be substantially a same as the incline angle of the fifth surface portion 40e of the front surface of the semiconductor substrate 40. The sub-trench 71 may reach the scribe region 3 or may partially or entirely positioned in the scribe region 3.

For example, at the front surface of the semiconductor substrate 40, during etching for forming the outer peripheral step 25, while the fourth surface portion 40d of the front surface of the semiconductor substrate 40, in a vicinity of the interface with the fifth surface portion 40e, tends to be recessed slightly deeper than the chip end side by etching, a depth of this recess is shallow compared to the depth d1 of the sub-trench 71. In the third embodiment, the sub-trench 71 is formed by actively and selectively removing the fourth surface portion 40d of the front surface of the semiconductor substrate 40.

The depth d1 of the sub-trench 71 is about a depth at which the sub-trench 71 terminates in the channel stopper region 32 and, for example, is about 0.1 μm or more but not more than 1 μm. The sub-trench 71, for example, may be formed by, for example, etching or the like before or after the channel stopper region 32 is formed after the etching for forming the outer peripheral step 25 at the front surface of the semiconductor substrate 40, in the method of manufacturing the semiconductor device 10 according to the first embodiment.

The insulating layer 33 is provided on the fourth surface portion 40d of the front surface of the semiconductor substrate 40, along an inner wall of the sub-trench 71. At the fourth upper surface portion 33d of the insulating layer 33, preferably, a groove 72 corresponding to the depth d1 of the sub-trench 71 may be formed. The surface protective film 34 covers the sub-trench 71 via the insulating layer 33. Provided the depth d1 of the sub-trench 71 is not more than about 1 μm, the incline angle of the fifth upper surface portion 34e of the surface protective film 34 is a same as that in the first embodiment.

As described, according to the third embodiment, an effects similar to the first embodiment may be obtained. Moisture that flows in from the outer peripheral end of the surface protective film and flows along the interface between the surface protective film and the insulating layer in a direction to the center of the chip remains within the sub-trench the outer peripheral step of the front surface of the semiconductor substrate and within the groove at the upper surface of the insulating layer above the sub-trench and does not easily flow to the chip center, whereby the effect of improving the moisture resistance of the semiconductor device is further enhanced.

In the foregoing, the present disclosure is not limited to the embodiments described above and various modifications not departing from the spirit of the disclosure are possible. For example, in the center portion of the active region, instead of the MOSFET device structure, a device structure of an IGBT or diode may be formed. Further, in the embodiments, while a first conductivity type is assumed to be an n-type and a second conductivity type is assumed to be a p-type, the present disclosure is similarly implemented when the first conductivity type is a p-type and the second conductivity type is an n-type.

The semiconductor device according to the present disclosure achieves an effect in that moisture resistance is improved and increases in cost may be suppressed.

As described, the semiconductor device according to the present disclosure is useful for power semiconductor devices used in power converting equipment, power source devices of various types of industrial machines, etc. and is particularly applicable to semiconductor devices having a wide band gap semiconductor as a material.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having a first main surface and a second main surface opposite to each other, the semiconductor substrate further having:
an active region through which a main current flows, and
a termination region surrounding a periphery of the active region in a plan view of the semiconductor device;
an insulating layer covering the first main surface of the semiconductor substrate in the termination region; and
a surface protective film provided on the insulating layer in the termination region, wherein
the first main surface has
a first portion at an outer periphery of the semiconductor substrate, and
a second portion closer to the active region than is the first portion, the first portion being recessed to be closer to the second main surface of the semiconductor substrate than is the second portion, thereby forming a step with the second portion, and
the surface protective film covers the step, via the insulating layer.

2. The semiconductor device according to claim 1, wherein
the surface protective film terminates above the first portion, and
a portion of the surface protective film above the first portion has an inclined surface, which is inclined a predetermined angle with respect to the first portion.

3. The semiconductor device according to claim 1, wherein
the first main surface has a third portion connecting the first portion and the second portion, so that the step between the first portion and the second portion forms a tapered shape, the third portion having an incline angle of 45 degrees or more but not more than 90 degrees with respect to the second portion.

4. The semiconductor device according to claim 1, wherein
the first main surface has a third portion connecting the first portion and the second portion, so that the step between the first portion and the second portion forms a reverse tapered shape, the third portion having an incline angle of 45 degrees or more but not more than 90 degrees with respect to the first portion.

5. The semiconductor device according to claim 1, wherein
the first portion has a sub-trench, and
the insulating layer is provided along an inner wall of the sub-trench.

6. The semiconductor device according to claim 5, wherein
the sub-trench has a depth of 0.1 μm or more but not more than 1 μm.

7. The semiconductor device according to claim 1, further comprising a channel stopper region provided along the step, at the outer periphery of the semiconductor substrate.

8. The semiconductor device according to claim 1, wherein
the surface protective film contains polyimide.

9. A semiconductor device, comprising:
a semiconductor substrate having a first main surface and a second main surface opposite to each other, the semiconductor substrate further having:
an active region through which a main current flows, and
a termination region surrounding a periphery of the active region in a plan view of the semiconductor device;
a channel stopper region provided in the termination region at an outer periphery of the semiconductor substrate;
an insulating layer covering the first main surface of the semiconductor substrate in the termination region; and
a surface protective film provided on the insulating layer in the termination region, wherein
the channel stopper region is provided in the semiconductor substrate at the first main surface thereof,
the first main surface has
a first portion at the channel stopper region, extending a predetermined width toward the active region from the outer periphery of the semiconductor substrate, and
a second portion closer to the active region than is the first portion, the first portion being recessed to be closer to the second main surface of the semiconductor substrate than is the second portion, thereby forming a step with the second portion, and
the surface protective film covers the step, via the insulating layer.

10. The semiconductor device according to claim 9, wherein
the surface protective film terminates above the first portion, and
a portion of the surface protective film above the first portion has an inclined surface, which is inclined a predetermined angle with respect to the first portion.

11. The semiconductor device according to claim 9, wherein
the first main surface has a third portion connecting the first portion and the second portion, so that the step between the first portion and the second portion forms a tapered shape, the third portion having an incline angle of 45 degrees or more but not more than 90 degrees with respect to the second portion.

12. The semiconductor device according to claim 9, wherein
the first main surface has a third portion connecting the first portion and the second portion, so that the step between the first portion and the second portion forms a reverse tapered shape, the third portion having an incline angle of 45 degrees or more but not more than 90 degrees with respect to the first portion.

13. The semiconductor device according to claim 9, wherein
the first portion has a sub-trench, and
the insulating layer is provided along an inner wall of the sub-trench.

14. The semiconductor device according to claim 13, wherein
the sub-trench has a depth of 0.1 μm or more but not more than 1 μm.

15. The semiconductor device according to claim 9, wherein
the channel stopper region extends toward the active region from the first portion and along the step, and reaches the second portion.

16. The semiconductor device according to claim 9, wherein
the surface protective film contains polyimide.
